(19) United States
(12) Patent Application Publication
(10) Pub. No.: US 2002/0028558 A1
(43) Pub. Date: Mar. 7, 2002

(54) Method for forming gate electrode of MOS type transistor

(76) Inventor: Kuk-seung Yang, Seoul (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/837,404

(22) Filed: Apr. 18, 2001

(30) Foreign Application Priority Data
Apr. 18, 2000 (KR) 2000-20447

(51) Int. Cl. H01L 21/336

(52) U.S. Cl. 438/303; 438/306

(57) ABSTRACT

A method for forming a gate electrode for a MOS type transistor including formation of an insulating layer on a portion of a semiconductor substrate is not used for the gate electrode. A spacer is formed on the sides of the insulating layer and a gate oxide and gate electrode layers are stacked on the portion of the semiconductor substrate that is used for forming the gate. Source/drain regions are formed by implanting ions after removing the insulating layer. A plug poly is formed in the opening portion left by the removal of the insulating layer. The spacer is then removed to allow LDD ion implantation true openings left by removal of the spacer. Prior to the LDD ion implantation, however, rapid thermal annealing is performed to activate the source/drain regions and the gate electrode, thereby effecting formation of a short effective channel of the gate, which is advantageous in high density integrated circuits.

### BACKGROUND OF THE INVENTION

1. Field of the Invention

The disclosed method relates to a method for forming a gate electrode of a MOS (Metal Oxide Semiconductor) type transistor, and in particular to a method for forming a gate electrode of a MOS type transistor that can form a short effective channel length of the gate electrode by controlling an order of implanting ions to a LDD (Lightly Doped Drain) ions implantation region and a source/drain region of a gate.

2. Description of the Background Art

In general, a MOSFET (MOS field effect transistor) is a field effect transistor in which a gate formed on a semiconductor substrate is isolated from a semiconductor layer by a thin oxide silicon layer. The MOSFET has several advantages such as impedance is not lowered like a junction type transistor, the diffusion process is simple, and separation between devices is unnecessary and, thus, the MOSFET device is suited for high-density integration.

The gate of the MOS type transistor is first formed by etching a gate electrode constructed with a gate oxide layer and a doped silicon layer or a tungsten silicide layer on a semiconductor substrate. Then, a LDD ion implantation region and a source/drain region are formed by implanting ions in an active region of the semiconductor substrate.

FIG. 1 illustrates a method for forming a general MOS type gate electrode. Referring to FIG. 1, a gate oxide layer 2, a gate electrode layer 3, and an insulating layer 4 are shown stacked on the semiconductor substrate 1. A gate is then formed through a masking etching process. A LDD (Lightly Doped Drain) is formed by implanting ions on both side surfaces of the gate and thereafter, an oxide layer 6 is stacked on the gate and then a spacer 5 is formed on the side of the gate using a blanket etch.

Thereafter, a source/drain region 7 is formed at the active region by implanting ions again. A RTP (Rapid Thermal Annealing) process is then performed to activate the implanted ions.

However, when the RTP process is performed after implanting ions, the ions become diffused into a channel at the lower part of the gate electrode. During this diffusion, a device having a gate with a long channel length is not significantly affected. In a high-density semiconductor device having a single channel, however, the integrity of the device is significantly affected. Thus, the conventional method is limited when attempting to achieve of a high integration of a device.

### SUMMARY OF THE INVENTION

In order to overcome the limitations of the conventional art, the disclosed method includes a method for forming the gate electrode for a MOS type transistor including first disposing a first insulating layer on at least one selected region of a semiconductor substrate except for at least one portion of the semiconductor substrate that is to be used for forming a gate. A first spacer is then disposed on at least one side of the first insulating layer and then a gate oxide layer and a gate electrode layer are sequentially disposed on the portion of the semiconductor substrate that is to be used for forming the gate. The first insulating layer is then removed to form a first opening portion through which ions are implanted onto the semiconductor substrate to form a source/drain region. A polysilicon layer is next buried in the first opening portion after the step of implanting the ions through the opening and a planarization process of the polysilicon layer is then performed to form a plug poly. Next, the first spacer is removed to form a second opening portion into which ions are implanted onto the semiconductor substrate to form a Lightly Doped Drain ion implantation region in the semiconductor substrate. Finally, a second insulating layer is buried in the second opening portion after the implantation of ions through the second opening and a planarization process of the second insulating layer is then performed to form a second spacer. This method achieves a short effective channel length of the gate electrode, which affords a smaller area needed for the gate electrode and, thus, is conducive for integrated circuits having high density.

### BRIEF DESCRIPTION OF THE DRAWINGS

The disclosed method is described with reference to the accompanying drawings, which are given only by way of illustration, wherein:

FIG. 1 is a view illustrating a method for forming a general MOS type gate electrode in accordance with the conventional art;

FIGS. 2a to 2f are views sequentially illustrating a method for forming a gate electrode according to an embodiment of the disclosed method; and

FIGS. 3a to 3f are views sequentially illustrating a method for forming a gate electrode according to another embodiment of the disclosed method.

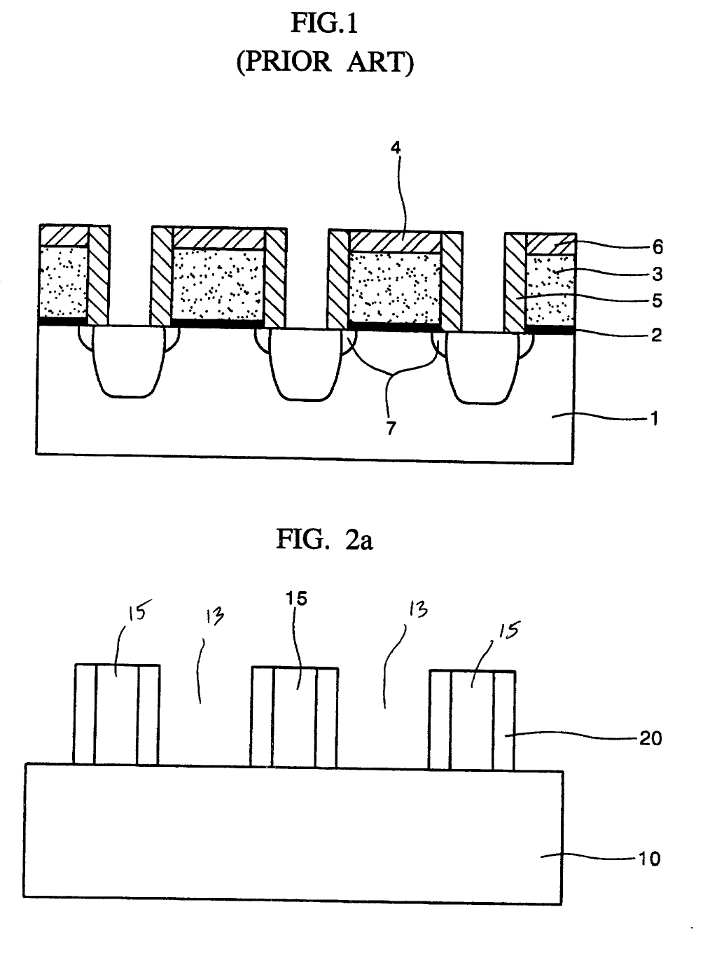

### DETAILED DESCRIPTION OF THE PREFERRED EMBODIMENTS

A method for forming a gate electrode of MOS type transistor will be described in detail with reference to the accompanying drawings.

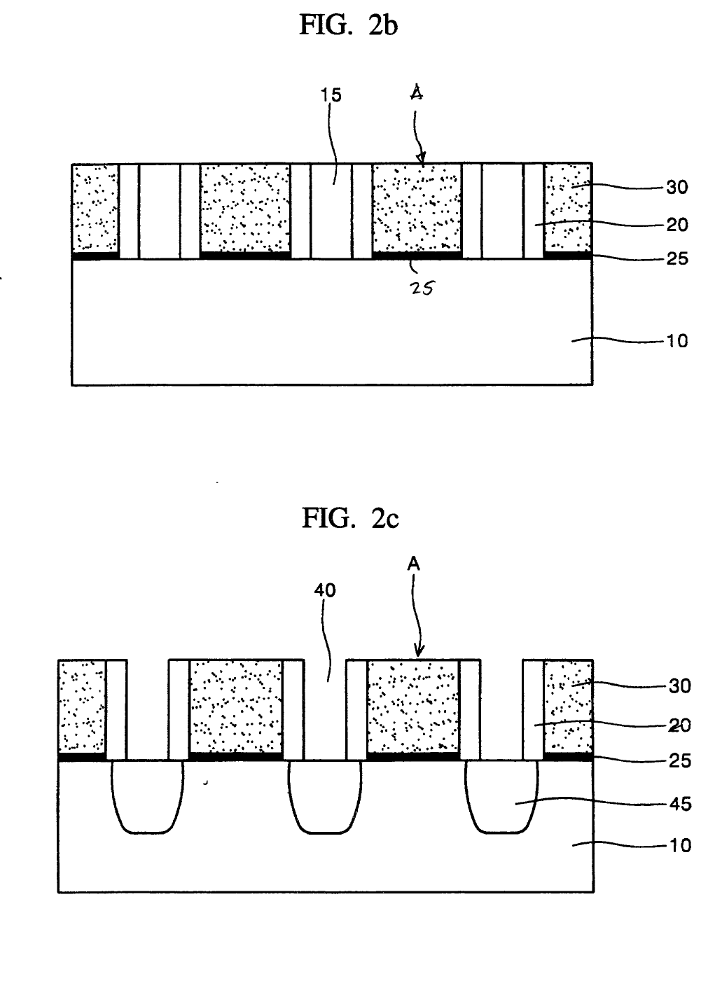

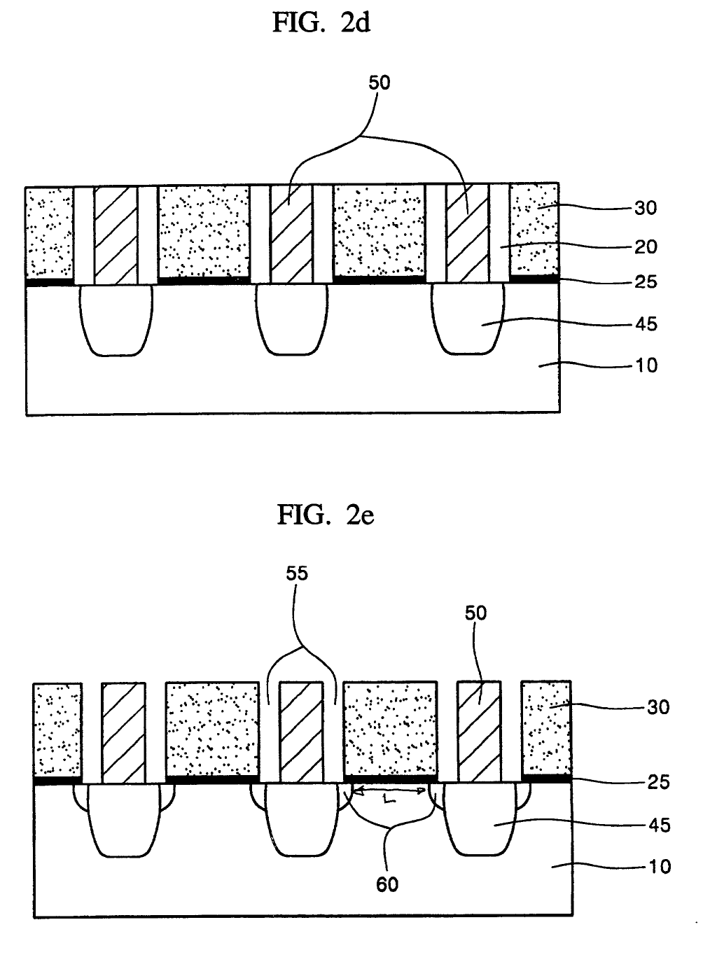

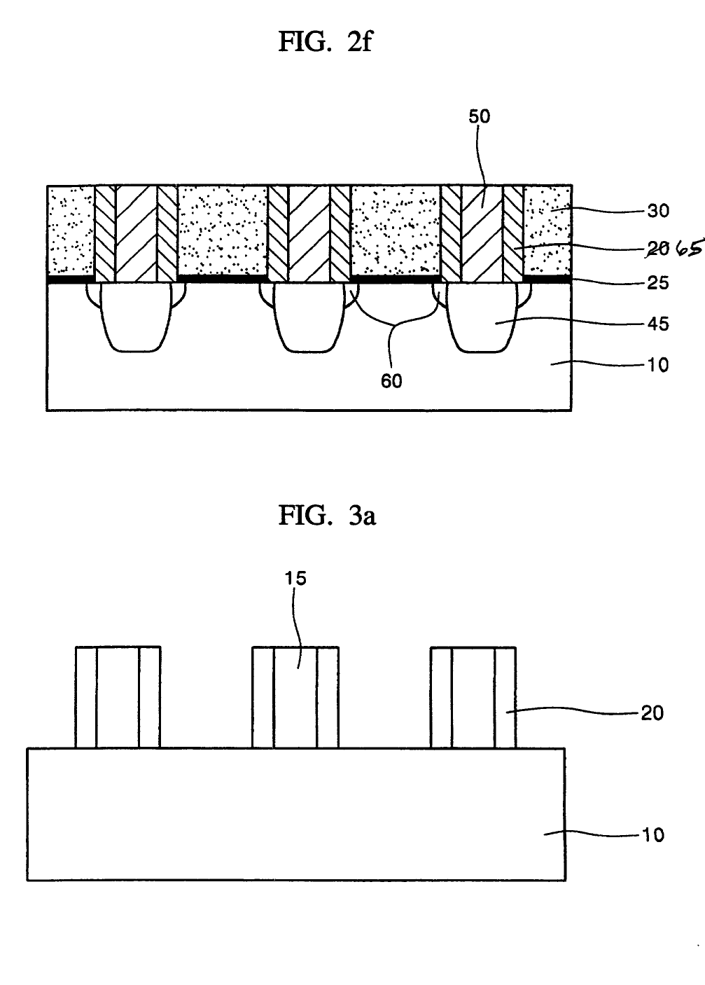

Referring to FIG. 2a, an insulating layer 15 with the thickness of about 1000-5000 Å is formed on the semiconductor substrate 10 except a portion 13 used for later forming a gate. A first spacer 20 with the thickness of about 200-2000 Å is next formed on sides of the insulating layer 15.

Referring to FIG. 2b, after the above-described process is performed, a gate A is formed by sequentially stacking a gate oxide layer 25 and a gate electrode layer 30 at portion 13 (as shown in FIG. 2a) for forming a gate.

The gate oxide layer 25 is a tantalum oxide layer or any other known gate oxide material such as silicon dioxide (SiO₂). The gate electrode layer 30 is formed by using a doped or undoped polysilicon layer or a metal silicide layer. Preferably, the gate electrode layer 30 is formed by using an undoped polysilicon layer.

Referring to FIG. 2c, after the above process is performed, a source/drain region 45 is formed at the semiconductor substrate 10 by implanting ions through a first opening part 40, which is formed by removing the insulating layer 15.

Referring to FIG. 2d, after the above process is completed, a polysilicon layer is buried in the first opening part 40. A planarization process of the buried layer is then performed, thereby forming a plug poly 50.

Referring to FIG. 2e, after the previous process is complete, a LDD ion implantation region 60 is formed into the semiconductor substrate 10 by implanting ions through a second opening portion 55, which is formed by removing the first spacer 20. Prior to the formation of the LDD ion implantation region 60, a rapid thermal annealing process is first performed in order to activate the source/drain region 45 and the gate electrode A. At this time, an effective length of the gate electrode A is formed as “L”, which is the length between the LDD ion implantation regions 60.

Referring to FIG. 2f, after the above process is performed, an insulating layer is buried in the second opening portion 55 (shown in FIG. 2e) and a planarization process of the buried insulating layer is performed, thereby forming a second spacer 65. It is noted that when performing the planarization process of the gate electrode layer 30, a chemical mechanical planarization (CMP) grinding process or an Etch Back process is used.

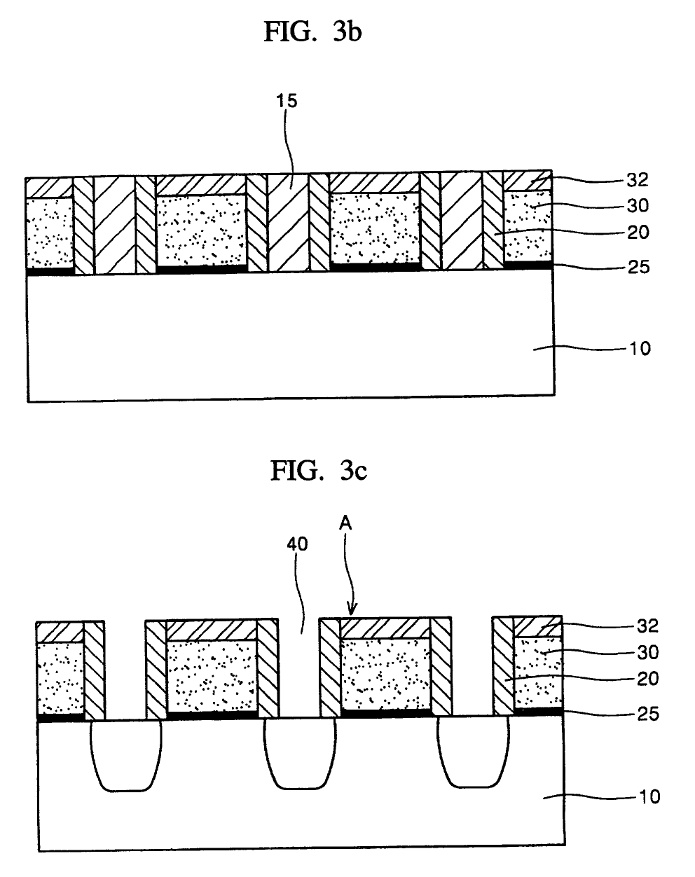

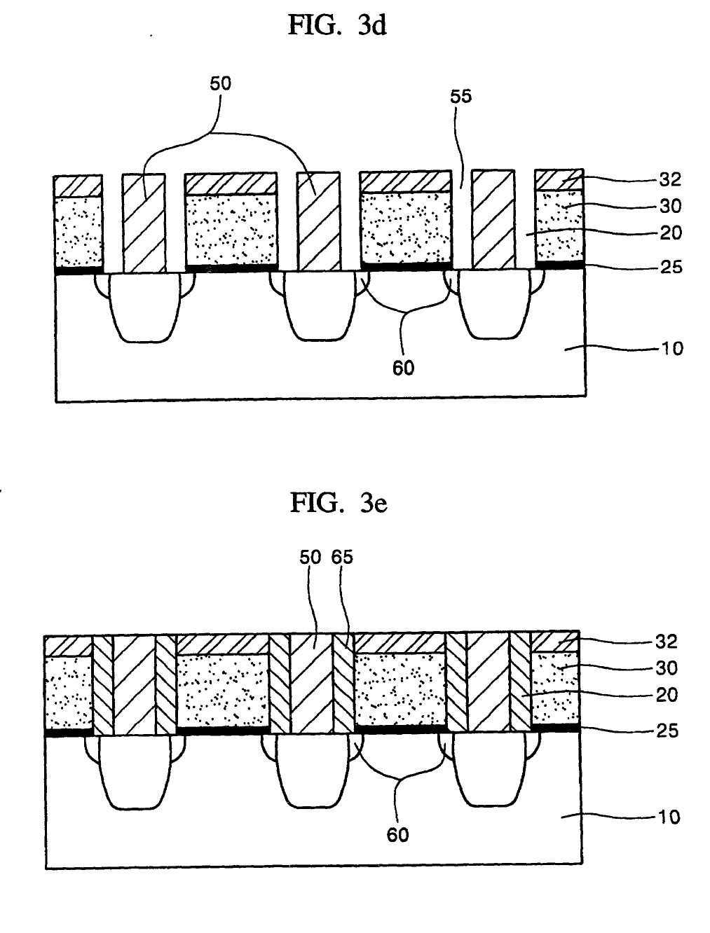

FIGS. 3a to 3f are views sequentially illustrating a method for forming a gate electrode in accordance with another embodiment of the disclosed method. In this embodiment, an additional hard mask 32 is stacked on the gate electrode layer 30 of the gate A. Since the method for forming the other parts in this embodiment is the same as that of the previously described embodiment, a detailed explanation will be omitted.

The method for forming a gate electrode for a MOS type transistor according to the disclosed method is efficient, since an insulating layer is formed at a portion that is not used to form a gate electrode on a semiconductor substrate and a first spacer is formed on side surfaces of the insulating layer. A gate oxide layer and a gate electrode layer are then stacked on a portion of the substrate used to form the gate. A source/drain region is formed by implanting ions after removal of the insulating layer. A plug poly is then formed at the resulting opening, and a LDD ion implanting region is formed by implanting ions through a second opening portion. This method achieves a short effective channel length of the gate electrode, thereby allowing easy constriction of the device with high density integrated circuit environment.

As the disclosed method may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A method for forming a gate electrode for a MOS type transistor, comprising the steps of:
disposing a first insulating layer on at least one selected region of a semiconductor substrate except for at least one portion of the semicondutor substrate that is used for forming a gate;
disposing a first spacer on at least one side of the first insulating layer;
sequentially diposing a gate oxide layer and a gate electrode layer on the portion of the semiconductor substrate that is used for forming the gate;
removing the first insulating layer to form a first opening portion;
implanting ions through the first opening portion onto the semiconductor substrate to form a source/drain region;
burying a polysilicon layer in the first opening portion after the step of implanting ions through the first opening and thereafter performing a planarization process of the polysilicon layer to form a plug poly;
removing the first spacer to form a second opening portion;
implanting ions through the second opening portion onto the semiconductor substrate to form a Lightly Doped Drain ion implantation region in the semiconductor substrate; and
burying a second insulating layer in the second opening portion after the step of implanting ions through the second opening and thereafter performing a planarization process of the second insulating layer to form a second spacer.

2. The method for forming a gate electrode in accordance with claim 1, wherein the first insulating layer has a thickness between about 1000 angstroms to about 5000 angstroms.

3. The method for forming a gate electrode in accordance with claim 1, wherein the first spacer has a thickness between about 200 angstroms to about 2000 angstroms.

4. The method for forming a gate electrode in accordance with claim 1, wherein the gate oxide layer is a tantalum oxide layer.

5. The method for forming a gate electrode in accordance with claim 1, wherein the gate electrode layer is comprised of a polysilicon layer or a metal silicide layer.

6. The method for forming a gate electrode in accordance with claim 1, wherein one of a chemical mechanical planarization grinding process and an etch back process are used to perform planarization of the gate electrode layer.

7. The method for forming a gate electrode in accordance with claim 1, further comprising the step of disposing a hard mask on the gate electrode layer.

8. The method for forming a gate electrode in accordance with claim 1, wherein a rapid thermal annealing process is performed in order to activate the source/drain region and the gate electrode prior to the step of forming the LDD ion implantation region.
